(19) United States
(12) Patent Application Publication
(10) Pub. No.: US 2006/0220937 A1
(43) Pub. Date: Oct. 5, 2006

(54) Swept delta-sigma modulation direct digital synthesis

(76) Inventors: Michael E. Harrell, Colorado Springs, CO (US); Mark Wickert, Colorado Springs, CO (US)

Correspondence Address: Welsh & Katz, Ltd.;Jon P. Christensen, 22nd Floor, 120 South Riverside Plaza, Chicago, IL, 60606, US

(21) Appl. No.: 11/398,969

(22) Filed: Apr. 5, 2006

Related U.S. Application Data
(60) Provisional application No. 60/668,481, filed on Apr. 5, 2005.

(51) Int. Cl. H03M 3/00

(52) U.S. Cl. 341/143

(57) ABSTRACT

A method and apparatus are provided for modulating a signal. The method includes the steps of providing a radio frequency signal, determining a set of delta-sigma modulation coefficients based upon a frequency of the provided signal and delta-sigma modulating the generated radio frequency signal within a delta-sigma modulator using the generated set of delta-sigma modulation coefficients.

### FIELD OF THE INVENTION

The field of the invention relates to radio frequency systems and more particularly to chirped radio frequency transmitters.

### BACKGROUND OF THE INVENTION

Chirped radio frequency systems are generally known. Such systems typically operate over a frequency range where a frequency of transmission is swept through the frequency range. The chirp may be from a low frequency to a high frequency, or visa versa. An example of where a chirped radio signal may be used is radar.

Alternatively, chirping may also be used in communication systems. In chirped or frequency hopped communication systems, a transmitter typically operates within a repeating frame structure. As the transmitter proceeds through the frequency range, the transmitted signal may be modulated with an information stream.

A receiver intended to operate within a chirped communication system (other than radar) must be programmed to synchronize and receive the chirped signal. In order to synchronize the receiver with a transmitter, the transmitter typically transmits a pilot tone at a predetermined frequency as a means for the receiver to detect and synchronize with the transmitter. Once synchronized, an oscillator within the receiver is programmed to sweep the frequency range at the same rate as the transmitter. By mixing the swept frequency of the local oscillator with a swept signal from the transmitter, the information signal may be retrieved at the receiver.

Chirped communication systems have been found to be relatively resistant to noise because noise is typically limited to a portion of a spectrum. By sweeping an operating frequency through an operating range, chirped systems are more resistant to noise than other types of radio frequency systems.

While chirped systems are effective in avoiding most noise, they are still susceptible to internally generated spurious signals as they sweep frequencies. Accordingly, a need exists for a method of increasing the fidelity of chirped waveform generating systems.

### SUMMARY

A method and apparatus are provided for modulating a signal. The method includes the steps of providing a radio frequency signal, determining a set of delta-sigma modulation coefficients based upon a frequency of the provided signal and delta-sigma modulating the generated radio frequency signal within a delta-sigma modulator using the generated set of delta-sigma modulation coefficients.

### BRIEF DESCRIPTION OF THE DRAWINGS

FIG. 1 is a block diagram of a delta-sigma modulation system used in conjunction with a chirp signal in accordance with an illustrated embodiment of the invention;

FIG. 2 shows an alternate embodiment of the system of FIG. 1;

FIG. 3 shows a system for correcting phase delay that may be used with the system of FIG. 1;

FIG. 4 shows pole zero plots with a noise transfer function designed to operate under a predetermined set of conditions;

FIG. 5 is simulated results for the system similar to FIG. 1 showing a waterfall plot of a tracking 6^{th} order delta-sigma converter operating over a 100 to 400 MHz sweep with frequency slice decimation;

FIG. 6 shows simulated results for the system of FIG. 1 showing a normalized power spectrum of a downconverted 6^{th} order delta-sigma converter output for a 100 to 400 MHz sweep and a decimation factor of 2048;

FIG. 7 is a zoomed version of FIG. 6 showing the line structure about the swept frequency;

FIG. 8 shows simulated results for a downconverted 6^{th} order delta-sigma converter output operating over a 100 to 400 MHz sweep and a decimation factor of 64, which is equivalent to 1024 delta-sigma converter coefficient steps over a 65536 point simulation;

FIG. 9 is a waterfall plot of a tracking 8^{th} order delta-sigma modulator for a 100 to 400 MHz sweep, with frequency slice decimation;

FIG. 10 is a downconverted 8^{th} order delta-sigma converter output for a 100 to 400 MHz sweep, R=30 and a decimation factor of 64, which is equivalent to 1024 delta-sigma converter coefficient steps over a 65536 point simulation;

FIG. 11 is a zoomed downconverted 8^{th} order delta-sigma modulator output for a 100 to 400 MHz sweep, R=30, and a decimation factor of 64, which is equivalent to 1024 delta-sigma modulator coefficient steps over the 216 point simulation;

FIG. 12 is a downconverted 8^{th} order delta-sigma modulator output for a 100 to 400 MHz sweep, R=30, and a decimation factor of 256, which is equivalent to 1024 delta-sigma modulator coefficient steps over a 218 point simulation;

FIG. 13 is a zoomed downconverted 8^{th} order delta-sigma modulator output for a 100 to 400 MHz sweep, R=30, and a decimation factor of 256, which is equivalent to 1024 delta-sigma modulator coefficient steps over the 218 point simulation.

### DETAILED DESCRIPTION OF AN ILLUSTRATED EMBODIMENT

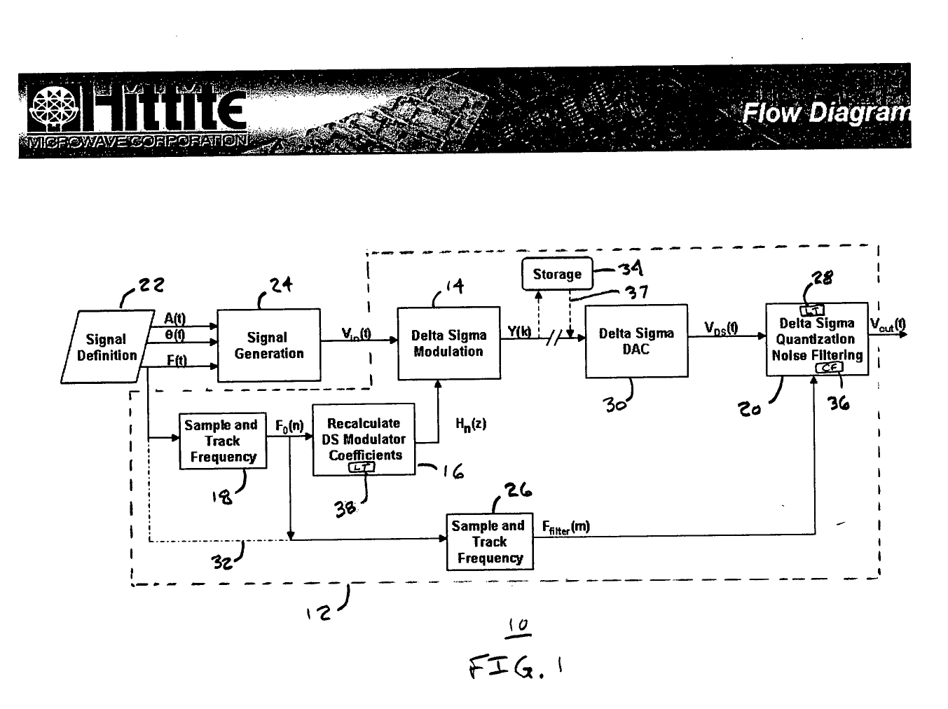

FIG. 1 is a block diagram of a chirped transmitter 10, shown generally in accordance with an illustrated embodiment of the invention. In general, the system 10 uses a delta-sigma modulation system 12 to spread quantization noise of a modulated signal V_{DS}(t) outside of a passband of the chirped signal.

As is well-known to those of skill in the art, it has not been possible in the past to use delta-sigma modulators with chirped radio frequency transmission systems because delta-sigma modulators have a fixed, narrow passband. Under illustrated embodiments of the invention, the claimed delta-sigma modulator system 12 provides a variable frequency pass band by varying a set of delta-sigma modulator coefficients, aᵢ(n), gᵢ(n), thus varying the transfer function, Hₙ(z) of the delta-sigma modulator 14

The delta-sigma modulation system 12 includes a bandpass delta-sigma modulator 14, a coefficients processor 16, sampling processors 18, 26 and a quantization processor 20. The delta-sigma modulator 18 and quantization filter 20 may operate under any of a number of different formats (e.g., continuous time (analog delta-sigma modulation), discrete time (digital delta-sigma modulation), etc.). In order to accommodate the chirped input signal Vᵢₙ(t), the operating parameters of the delta-sigma modulator 14 and, if required, the operating parameters of filter 20 are continuously updated based upon an operating frequency of the chirped input signal Vᵢₙ(t).

In general, the chirped input signal Vᵢₙ(t) to the system 10 may be provided in any of a number of different formats (e.g., a real, time varying analog signal; a sampled discrete time signal; a sampled and quantized signal; etc.). In the case of the real, time varying input signal, Vᵢₙ(t) may have an amplitude A(t), a phase θ(t) and a frequency (or frequency gradient) F(t).

The signal Vᵢₙ(t) may be generated within a signal generation processor (chirp modulator) 24. The signal generation processor 24 may accept as inputs a value for the amplitude A(t), a phase θ(t) and frequency F(t) from a signal definition processor 22. The amplitude A(t) and phase θ(t) may incorporate an information signal where the system 10 is used within a communication system.

The chirp of the input signal Vᵢₙ(t) may be linear or non-linear. In this regard, the change of frequency of the chirped signal Vᵢₙ(t) may be linear, non-linear (e.g. based upon a polynomial), or discontinuous (e.g. frequency hopping).

In order to determine a set of coefficients, aᵢ(n), gᵢ(n), and transfer function Hₙ(z), a sample and track frequency processor 18 may perform the function of sampling and tracking the chirped signal Vᵢₙ(t) in real time to determine a frequency Fₒ(n) of the signal. The determination of frequency is transferred to a coefficients processor 16 that identifies a set of coefficients and transfer function Hₙ(z) for that time interval. The set of coefficients and transfer function Hₙ(z) may be identified by calculating the coefficients in real-time or by retrieval of the coefficients, aᵢ(n), gᵢ(n), from a look up table 38. Where based upon the use of a look up table 38, the determined frequency Fₒ(n) is used as an index to retrieve the coefficients associated with the determined frequency Fₒ(n).

Where a transfer function H(z) is for a 4^{th} order delta-sigma modulator 14, the coefficients may be determined by the equation

$${H}_{n} ( z ) = {( \frac{{z}^{2} + 2 {a}_{n} z + 1}{z ( z + {a}_{n} )} )}^{2} ,$$

where aₙ,=cos(F(n)* T * 2π) and where T is the sample period of the delta-sigma modulator 14. The transfer function H(z) may be any high order delta-sigma modulator. More specifically, where the delta-sigma modulator 14 is a digital signal processor (DSP) the calculated coefficients used to define the transfer function Hₙ(z) may be an ABCD matrix describing the system. In a continuous time analog delta-sigma modulator 14, the coefficients used to define the transfer function Hₙ(z) would be voltages or currents used to tune the LC or Gₘ-C resonators and amplifier gains. In discrete time switched-capacitor implementations of the delta-sigma modulator 14, the coefficients used to define the transfer function Hₙ(z) would be feedback and feed forward gain coefficients.

In any case, the coefficients used to define the transfer function Hₙ(z) are determined and transferred to the delta-sigma modulator 14. Within the delta-sigma modulator 14, the resulting transfer function Hₙ(z) is used by the delta-sigma modulator 14 to modulate the chirped signal Vᵢₙ(t). The modulated chirp signal Vᵢₙ(t) from the delta-sigma modulator 14 may then be regenerated into an analog waveform within a delta-sigma digital to analog converter 30.

Following regeneration, a fixed or tunable filter 20 may filter the modulated signal's quantization noise based upon the frequency. In this case, a second sample and track frequency processor 26 samples and determines a frequency of the chirped signal Vᵢₙ(t). The second sample and track processor 26 may use the output Fₒ(n) of the first sample and track frequency processor 18 as an input or, alternatively, may independently determine frequency through a connection 32 to the signal processor 22. The determined frequency F_{filter}(m) from the second sample and track processor 26 may be used by a filter coefficients processor 36 to select or adjust a set of quantization noise filter parameters based upon the frequency of the modulator transfer function H(z). The filter parameters selected for the quantization filter 20 may be generated by the filter coefficients processor 36 based upon a filter performance equation or retrieved from a look up table 28.

It should be noted in this regard that the determination of frequency for purposes of adjusting filter parameters in the quantization filter 20 need only be performed at some rate 1/Tₘ. In contrast, the determination of frequency for selection of coefficients Hₙ(z) would be performed at a faster rate 1/Tₙ.

Under an alternate embodiment, a delta-sigma modulated signal sequence may be generated for a number of different input signals Vᵢₙ(t) and saved in a storage unit (memory) 34 for later retrieval and use by an external device. In this case, the delta-sigma modulator 14 would function to pre-calculate the particular delta-sigma sequence based upon a corresponding segment of the signal Vᵢₙ(t). Once calculated, the delta-sigma modulator system 12 may send an identifier of the sequence to synchronize the regeneration of waveform Vᵢₙ(t) at a prescribed time. The memory 34, in turn, would output the sequence on the bus 37 to the waveform regenerator 30.

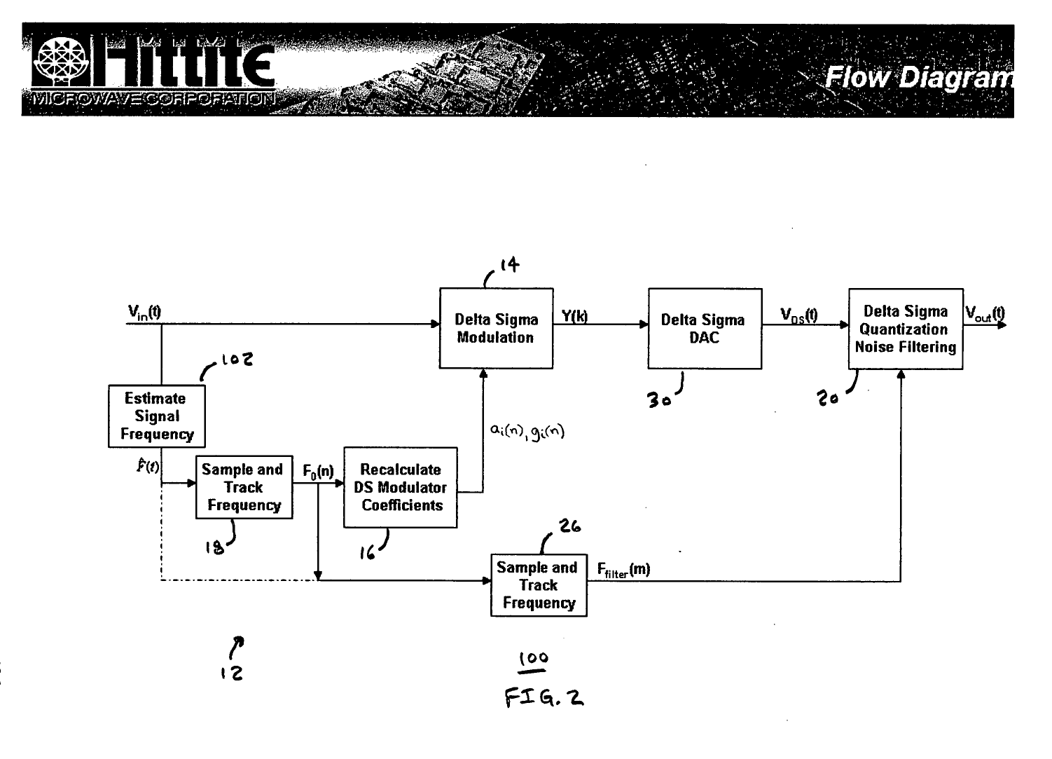

FIG. 2 depicts an alternate embodiment of the system 10 of FIG. 1 (now labeled 100). In FIG. 2, the system 100 receives an analog chirped signal Vᵢₙ(t). In this case, an estimate signal frequency processor 102 may estimate an instantaneous frequency of the input signal Vᵢₙ(t). The sample and track frequency processors 18, 26 may sample and track the instantaneous values as described above. In other regards, the system 100 may operate in substantially the same way as the system 10. This embodiment would track signals without a-priori knowledge of frequency.

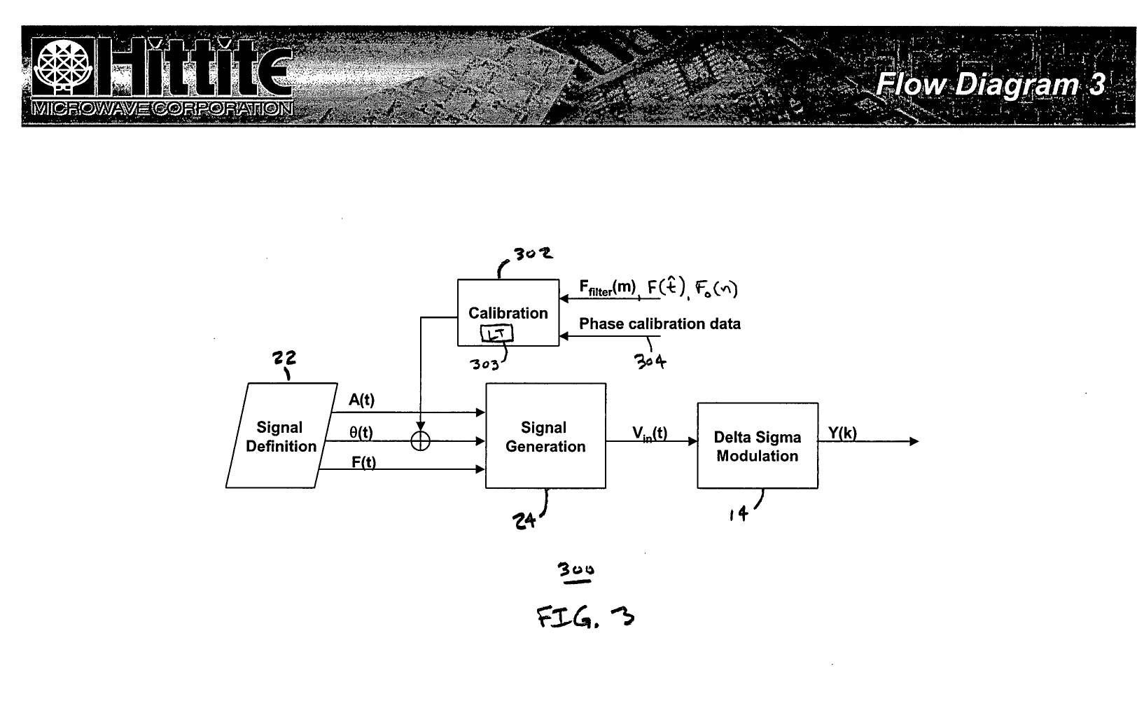

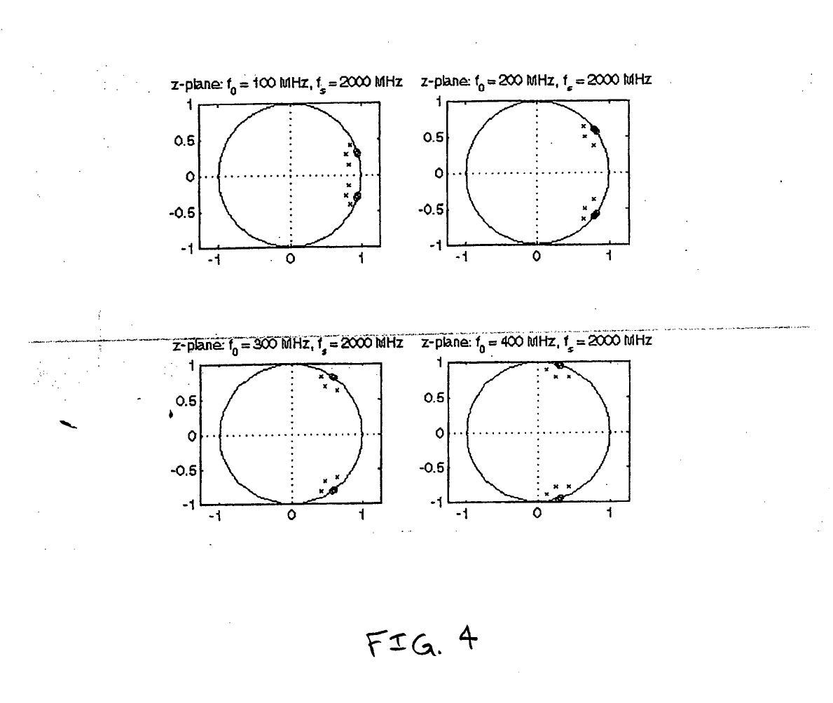

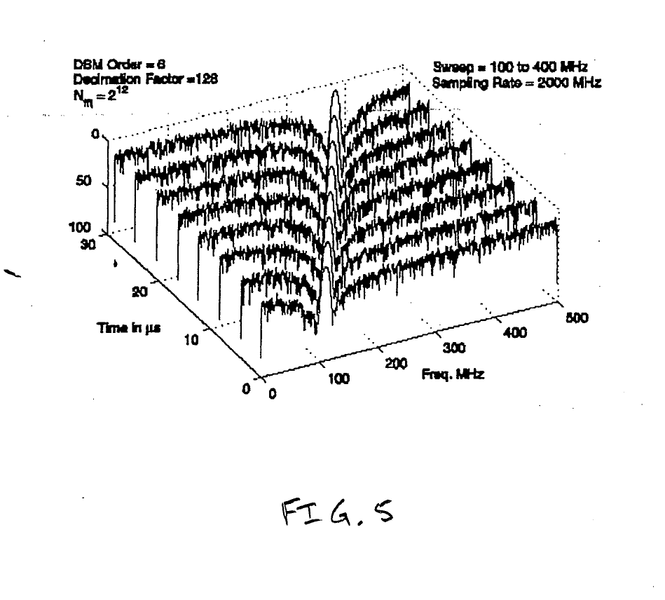

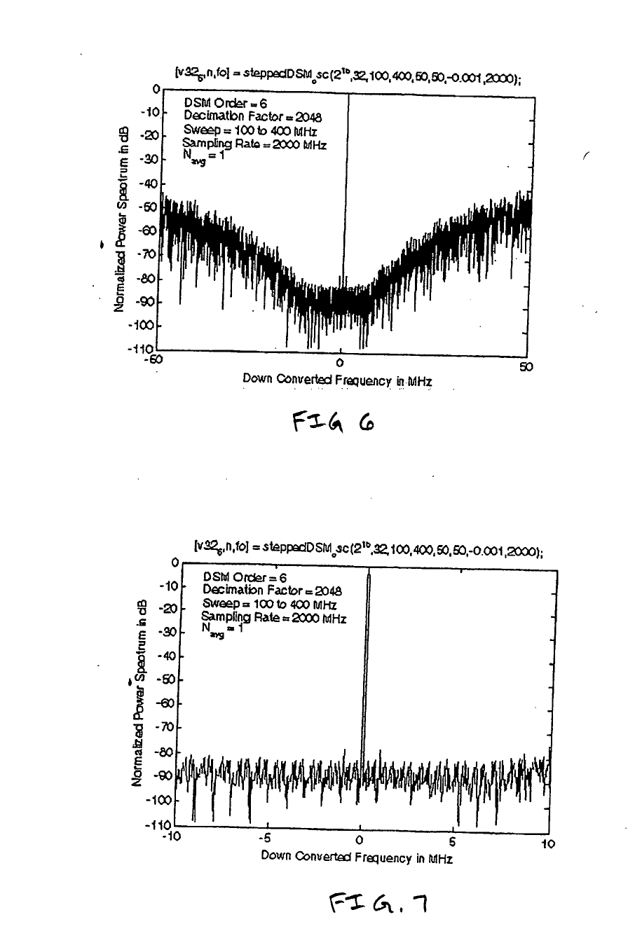

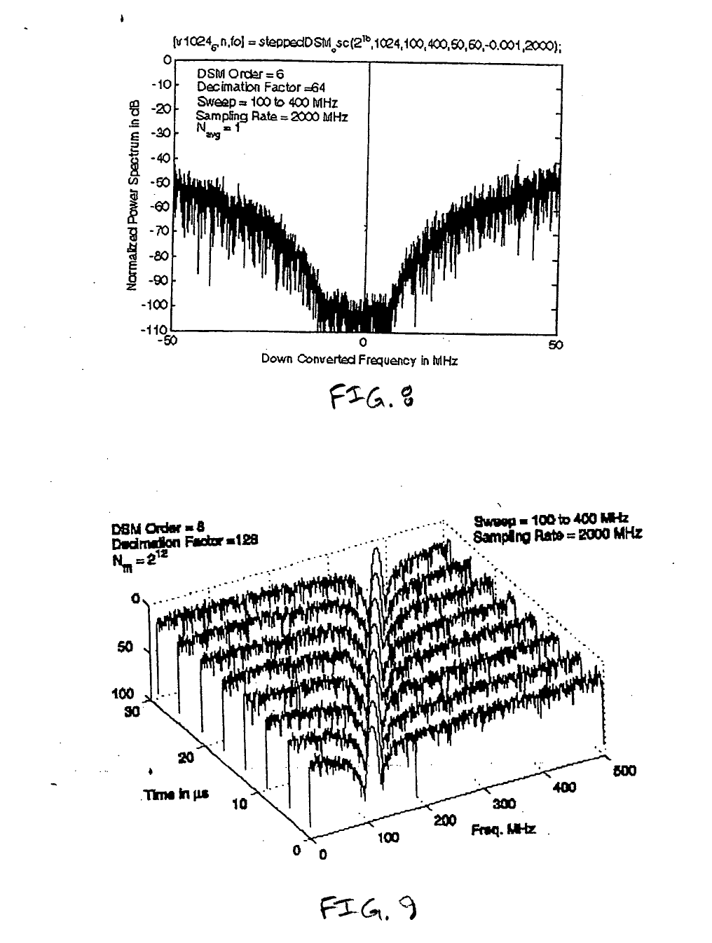

FIG. 3 depicts another alternate embodiment of the system 10 (now labeled 300). In the system 300, a feedback signal is used to correct for phase errors caused by the delta-sigma modulation system 12. In this case, it has been found that the phase error of the system 12 may be caused by group delay and phase variation of filter 20. In order to compensate for the phase error, a value of or change in the value of the frequency F_{filter}(m) from the sample and track frequency processor 26 is used in conjunction with phase calibration data 304 within a calibration processor 302 to adjust the phase value θ(t) of the input signal Vᵢₙ(t) to compensate for the delay. Additionally, F₀(n), or the estimated frequency \hat{F}(t) may be used to adjust θ(t). In this case, the frequency F_{filter}(m) may be used as an index to lookup a phase calibration data value 304 within the look up table 303 and add the value to the phase value θ(t).

FIG. 4 shows pole-zero plots of a delta-sigma modulator operated over a number of different frequencies with a predetermined set of coefficients Hₙ(z). In this example a noise transfer function (NTF) was chosen to operate with a sampling rate fₛ=2000 MHz, fₘᵢₙ=100 MHz and fₘₐₓ=400 MHz. The pole-zero plots of the NTF at different center frequencies clearly shows the range of center frequencies of operation with respect to the sampling rate. In FIG. 4 pole-zero plots are shown for fₒ=100, 200,300 and 400 MHz.

FIG. 5 shows a waterfall plot of spectral analysis simulation results for specific test cases. In this case, the input signal may be described by the equation
x[n]=Acos(2π(ƒₒ/ƒₛ)n+π(W/ƒₛ)n²/ƒₛT),
where A is amplitude, ƒₛ is the sampling frequency, ƒₒ is a starting frequency and W is the frequency change over the time interval T.

The configuration used in generating FIG. 5 includes a sampling rate of 2000 MHz, a linear sweep from 100 MHz to 400 MHz over 2¹⁶=65536 steps, which implies that W=300 MHz and T=32.768 micro-seconds. Other delta-sigma modulator parameter held fixed included the oversampling ratio R=50, and the sinusoid amplitude A=0.5. The decimation factor varied from a high of 2048 to a low of 64, in powers of two. Looking at this situation in terms of simulation parameters, the number of step changes in the delta-sigma modulator bandpass coefficients over each simulation test varied from a low of 32 to a high of 1024. A 6^{th} order delta-sigma modulator was simulated in this test.

FIG. 5 shows spectral slices over time at the output of the delta-sigma modulator. Since tracking down conversion is not utilized in this case, the spectrum of a chirping signal and the NTF of the delta-sigma modulator can be seen in each of the slices. Each slice is based upon a 4096 point FFT.

FIG. 6 shows the down converted spectrum (i.e., a 6^{th} order delta-sigma converter output for a 100 MHz to 400 MHz sweep) for a decimation factor of 2048 which is equivalent to 32 coefficient steps over the 65536 point simulation. FIG. 7 shows the pass band in more detail. The −77 dBc spurs seen in both figures appear to correspond to the delta-sigma modulator coefficient step rate of about 1 MHz in this example. When the delta-sigma modulator coefficient step rate is increased to roughly 32 MHz, the resulting spurs are shifted out of the pass band, as shown in FIG. 8. The remaining −95 dBc noise floor over a roughly 20 MHz bandwidth results in −145 dBc/Hz noise. No instability is apparent in the 6^{th} order system.

Simulations were also performed for 8^{th} order delta-sigma modulators with the same variation of factors in the previous example. The 8^{th} order provides a wider pass band which eases requirements on the post filter. No instability is apparent in the 8^{th} order system.

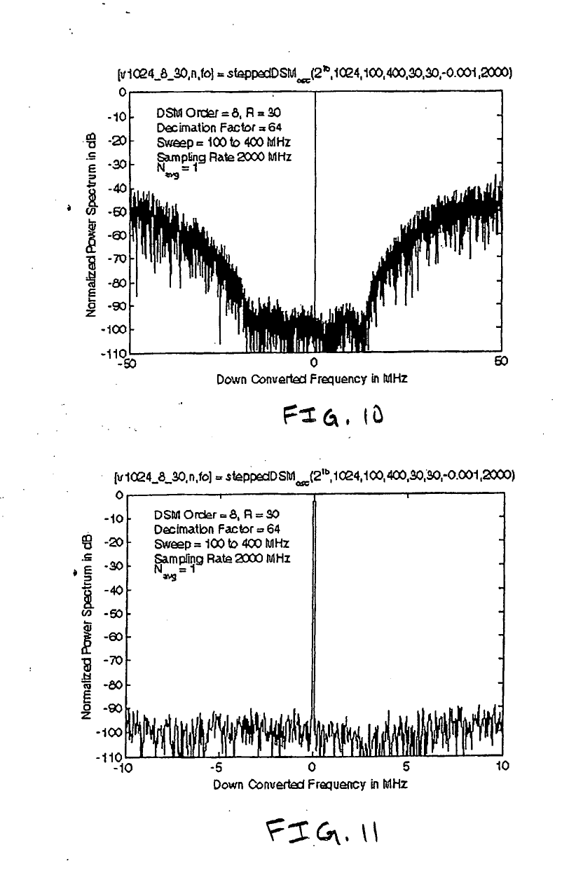

FIG. 9 is a waterfall plot for a 300 MHz sweep. FIG. 9 shows the downconverted spectrum shown in FIG. 10. The expanded pass band shown in FIG. 11 is free of significant spurs.

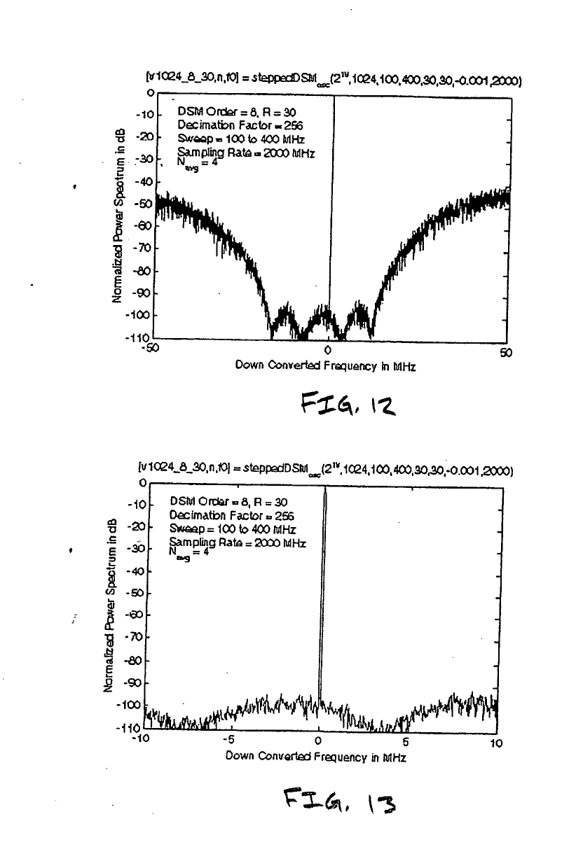

In order to see the underlying structure more clearly, four spectrums were averaged. In the resulting downconverted spectrum shown in FIG. 12, the four zeros of the NTF are now clearly visible as valleys in the pass band. FIG. 13 shows the expanded pass band is relatively clean and peaks at about −93 dBc. No spurs are visible above the noise floor.

A specific embodiment of a delta-sigma modulator system has been described for the purpose of illustrating the manner in which one possible alternative of the invention is made and used. It should be understood that the implementation of other variations and modifications of embodiments of the invention and its various aspects will be apparent to one skilled in the art, and that the various alternative embodiments of the invention are not limited by the specific embodiments described. Therefore, it is contemplated to cover all possible alternative embodiments of the invention and any and all modifications, variations, or equivalents that fall within the true spirit and scope of the basic underlying principles disclosed and claimed herein.

1. A method of modulating a signal comprising:
providing a chirped radio frequency signal;
determining a set of delta-sigma modulation coefficients based upon a frequency of the provided chirped signal; and
delta-sigma modulating the chirped signal within a delta-sigma modulator using the generated set of delta-sigma modulation coefficients.

2. The method of modulating the signal as in claim 1 wherein the step of determining the set of delta-sigma modulation coefficients further comprises calculating the set of delta-sigma modulation coefficients based upon a transfer function of the delta-sigma modulator.

3. The method of modulating the signal as in claim 1 wherein the step of determining the set of delta-sigma modulation coefficients further comprises retrieving the delta-sigma modulation coefficients from a look up table.

4. The method of modulating the signal as in claim 1 further comprising determining the frequency by sampling and tracking the provided signal.

5. The method of modulating the signal as in claim 1 further comprising calculating a set of quantization noise filtering parameters based upon the frequency of the provided signal.

6. The method of modulating the signal as in claim 1 further comprising filtering the delta-sigma modulated radio frequency signal using the calculated set of quantization noise filtering parameters.

7. The method of modulating the signal as in claim 1 further comprising adjusting a phase of the provided signal to compensate for phase delay within the modulator and filter.

8. The method of modulating the signal as in claim I wherein the step of adjusting a phase of the provided signal further comprises retrieving a phase calibration value from a look up table using frequency and change in frequency as a lookup index.

9. The method of modulating the signal as in claim 1 further comprising storing the delta-modulated chirped signal in a look up table as a delta-sigma sequence and retrieving the stored delta-sigma sequence for use when needed.

10. An apparatus for modulating a signal comprising:
a chirped radio frequency signal;
means for determining a set of delta-sigma modulation coefficients based upon a frequency of the provided chirped signal; and
means for delta-sigma modulating the chirped signal within a delta-sigma modulator using the generated set of delta-sigma modulation coefficients.

11. The apparatus for modulating the signal as in claim 10 wherein the means for determining the set of delta-sigma modulation coefficients further comprises means for calculating the set of delta-sigma modulation coefficients based upon a transfer function of the delta-sigma modulator.

12. The apparatus for modulating the signal as in claim 10 wherein the means for determining the set of delta-sigma modulation coefficients further comprises means for retrieving the delta-sigma modulation coefficients from a look up table.

13. The apparatus for modulating the signal as in claim 10 further comprising means for determining the frequency by sampling and tracking the provided signal.

14. The apparatus for modulating the signal as in claim 10 further comprising means for calculating a set of quantization noise filtering parameters based upon the frequency of the provided signal.

15. The apparatus for modulating the signal as in claim 14 further comprising means for filtering the delta-sigma modulated radio frequency signal using the calculated set of quantization noise filtering parameters.

16. The apparatus for modulating the signal as in claim 10 further comprising means for adjusting a phase of the provided signal to compensate for phase delay within the modulator and filter.

17. The apparatus for modulating the signal as in claim 10 wherein the means for adjusting the phase of the provided signal further comprises means for retrieving a phase calibration value from a look up table using frequency and change in frequency as a lookup index.

18. The apparatus for modulating the signal as in claim 10 further comprising means for storing the delta-modulated chirped signal in a look up table as a delta-sigma sequence and retrieving the stored delta-sigma sequence for use when needed.

19. An apparatus for modulating a signal comprising:
a chirped radio frequency signal;
a coefficients processor that determines a set of delta-sigma modulation coefficients based upon a frequency of the provided chirped signal; and
a delta-sigma modulator that delta-sigma modulates the chirped signal within a delta-sigma modulator using the generated set of delta-sigma modulation coefficients.

20. The apparatus for modulating the signal as in claim 19 wherein the coefficients processor further comprises a transfer function that calculates the set of delta-sigma modulation coefficients based upon a transfer function of the delta-sigma modulator.

21. The apparatus for modulating the signal as in claim 19 wherein the coefficients processor further comprises a look up table.

22. The apparatus for modulating the signal as in claim 19 further comprising a sample and track frequency processor that determines the frequency by sampling and tracking the provided signal.

23. The apparatus for modulating the signal as in claim 19 further comprising a filter coefficients processor that calculates a set of quantization noise filtering parameters based upon the frequency of the provided signal.

24. The apparatus for modulating the signal as in claim 23 further comprising a delta-sigma quantization noise filter that filters the delta-sigma modulated radio frequency signal using the calculated set of quantization noise filtering parameters.

25. The apparatus for modulating the signal as in claim 19 further comprising a calibration processor that adjusts a phase of the provided signal to compensate for phase delay within the modulator and filter.

26. The apparatus for modulating the signal as in claim 19 further comprising a look up table that stores the delta-modulated chirped signal as a delta-sigma sequence and that retrieves the stored delta-sigma sequence for use when needed.
